(19) United States
(12) Patent Application Publication
(10) Pub. No.: US 2016/0043209 A1
(43) Pub. Date: Feb. 11, 2016

(54) SEMICONDUCTOR DEVICE PROVIDED WITH HEMT

(71) Applicant: DENSO CORPORATION, Aichi (JP)

(72) Inventor: Kazuhiro OYAMA, Nishitokyo-city (JP)

(73) Assignee: DENSO CORPORATION, Kariya-city, Aichi-pref. (JP)

(21) Appl. No.: 14/780,753

(22) PCT Filed: Apr. 7, 2014
(86) PCT No.: PCT/JP2014/001980

§ 371 Date: Sep. 28, 2015

(30) Foreign Application Priority Data
Apr. 11, 2013 (JP) 2013-083173

(51) Int. Cl. H01L 29/778; H01L 29/423

(52) U.S. Cl. CPC H01L 29/7786; H01L 29/4236

(57) ABSTRACT

A semiconductor device includes: a normally-off type HEMT having a first semiconductor layer, a second semiconductor layer providing a heterojunction with the first semiconductor layer and generating a first two-dimensional electron gas layer, a gate recess arranged in the first semiconductor layer, an insulation film disposed on a wall surface of the gate recess, and a gate electrode disposed on the insulation film. The gate recess has a width of a bottom side narrower than an opening side. The gate electrode is disposed along a side surface of the gate recess. When a gate voltage is applied to the gate electrode, a second two-dimensional electron gas layer is provided in the second semiconductor layer to partially overlap the first two-dimensional electron gas layer.

### CROSS REFERENCE TO RELATED APPLICATION

This application is a U.S. national stage application of International Patent Application No. PCT/JP2014/001980 filed on Apr. 7, 2014 and is based on Japanese Patent Application No. 2013-83173 filed on Apr. 11, 2013, the disclosures of which are incorporated herein by reference.

### TECHNICAL FIELD

The present disclosure relates to a semiconductor device provided with a HEMT (i.e., High Electron Mobility Transistor).

### BACKGROUND

A semiconductor device provided with a normally-off HEMT has been proposed (see, for example, Patent Literature 1).

More specifically, the semiconductor device uses a substrate obtained by laminating an electron supply layer on an electron transit layer to form a heterojunction. The electron supply layer is provided with a gate recess that reaches the electron transit layer and runs perpendicularly to an interface between the electron transit layer and the electron supply layer. A gate electrode is provided on the gate recess via an insulation film. A source electrode and a drain electrode are provided on the electron supply layer.

In the semiconductor device as above, because the gate recess reaching the electron transit layer is provided, a two-dimensional electron gas layer generated by the heterojunction is not formed in the electron transit layer at a portion directly below a bottom surface of the gate recess.

When a voltage at or above a predetermined threshold value is applied to the gate electrode, a two-dimensional electron gas layer generated by a gate voltage is formed in the the electron transit layer at a portion directly below the gate electrode. Hence, a current path (channel) is formed between the source electrode and the drain electrode by the two-dimensional electron gas layer generated by the heterojunction and the two-dimensional electron gas layer generated by the gate voltage. A current thus flows between the source electrode and the drain electrode and the semiconductor device switches ON.

That is to say, the semiconductor device provided with the HEMT is capable of obtaining normally-off properties, according to which the channel between the source electrode and the drain electrode is OFF unless a gate voltage at or above the predetermined threshold value is applied to the gate electrode.

In the semiconductor device provided with the HEMT as above, however, the gate recess is provided perpendicularly to the interface between the electron transit layer and the electron supply layer. Hence, a two-dimensional electron gas layer generated by the gate voltage is hardly formed in the electron transit layer at a portion directly below the insulation film provided to side surfaces of the gate recess. Accordingly, both of a two-dimensional electron gas layer generated by the heterojunction and a two-dimensional electron gas layer generated by the gate voltage are hardly formed in the electron transit layer at the portion directly below the insulation film provided to the side surfaces of the gate recess. Hence, electron density in such a portion is low even when the semiconductor device switches ON. Consequently, a maximum current flowing through the semiconductor device decreases.

### PATENT LITERATURE

Patent Literature 1: JP-2012-124442 A

### SUMMARY

It is an object of the present disclosure to provide a semiconductor device.

According to an example aspect of the present disclosure, a semiconductor device includes: a normally-off type HEMT having a first semiconductor layer, a second semiconductor layer providing a heterojunction with the first semiconductor layer and generating a first two-dimensional electron gas layer at the heterojunction, a gate recess arranged in the first semiconductor layer, an insulation film disposed on a wall surface of the gate recess, and a gate electrode disposed on the insulation film. The gate recess has a width of a bottom side narrower than an opening side. The gate electrode is disposed along a side surface of the gate recess. When a gate voltage equal to or larger than a predetermined threshold value is applied to the gate electrode, a second two-dimensional electron gas layer generated by the gate voltage is provided in the second semiconductor layer so as to partially overlap the first two-dimensional electron gas layer.

In the above semiconductor device, the first and second two-dimensional electron gas layers overlap. Consequently, formation of a region having low electron density can be restricted and hence a decrease of a maximum current can be restricted.

### BRIEF DESCRIPTION OF DRAWINGS

The above and other objects, features and advantages of the present disclosure will become more apparent from the following detailed description made with reference to the accompanying drawings. In the drawings:

FIG. 1 is a sectional view of a semiconductor device provided with a HEMT according to a first embodiment of the present disclosure;

FIG. 2 is a view showing a relation of a maximum current with respect to an angle formed by respective side surfaces of a gate recess and an interface between an electron transit layer and an electron supply layer;

FIG. 3 is a sectional view of a modification of the semiconductor device provided with the HEMT according to the first embodiment of the present disclosure;

FIG. 4 is a sectional view of a semiconductor device provided with a HEMT according to a second embodiment of the present disclosure;

FIG. 5 is a sectional view of a modification of the semiconductor device provided with the HEMT according to the second embodiment of the present disclosure; and

FIG. 6 is a sectional view of a semiconductor device provided with a HEMT according to still another embodiment of the present disclosure.

### DETAILED DESCRIPTION

Hereinafter, embodiments of the present disclosure will be described according to the drawings. A description will be given by labeling same or equivalent portions with same reference numerals in respective embodiments below.

### First Embodiment

A first embodiment of the present disclosure will be described with reference to the drawings. A semiconductor device provided with a HEMT of the present embodiment uses a substrate 5 formed by sequentially laminating a support substrate 1, a buffer layer 2, an electron transit layer 3, and an electron supply layer 4. In the present embodiment, the electron supply layer 4 corresponds to a first semiconductor layer of the present disclosure and the electron transit layer 3 corresponds to a second semiconductor layer of the present disclosure.

An Si substrate, an SiC substrate, a GaN substrate, a sapphire substrate, and so on are used as the support substrate 1. A compound layer or the like to match a lattice constant of the support substrate 1 with a lattice constant of the electron transit layer 3 is used as the buffer layer 2. The buffer layer 2 is not in direct relation to an operation of the HEMT and may therefore be omitted particularly when the support substrate1 1 is a self-support substrate, such as a GaN substrate, or a sapphire substrate.

In the electron transit layer 3, first and second two-dimensional electron gas layers 6a and 6b having high electron density and functioning as a current path (channel) are formed in the vicinity of one surface on a side of the electron supply layer 4. For example, gallium nitride (GaN) is used as the electron transit layer 3.

The electron supply layer 4 having a larger band gap than the electron transit layer 3 is used. The electron supply layer 4 forms a heterojunction with the electron transit layer 3. The first two-dimensional electron gas layer 6a is thus formed by spontaneous polarization and piezoelectric polarization in the electron transit layer 3 in the vicinity of an interface with the electron supply layer 4. For example, aluminum gallium nitride (AlGaN) is used as the electron supply layer 4 as above.

The electron supply layer 4 is provided with a gate recess 7 reaching the electron transit layer 3.

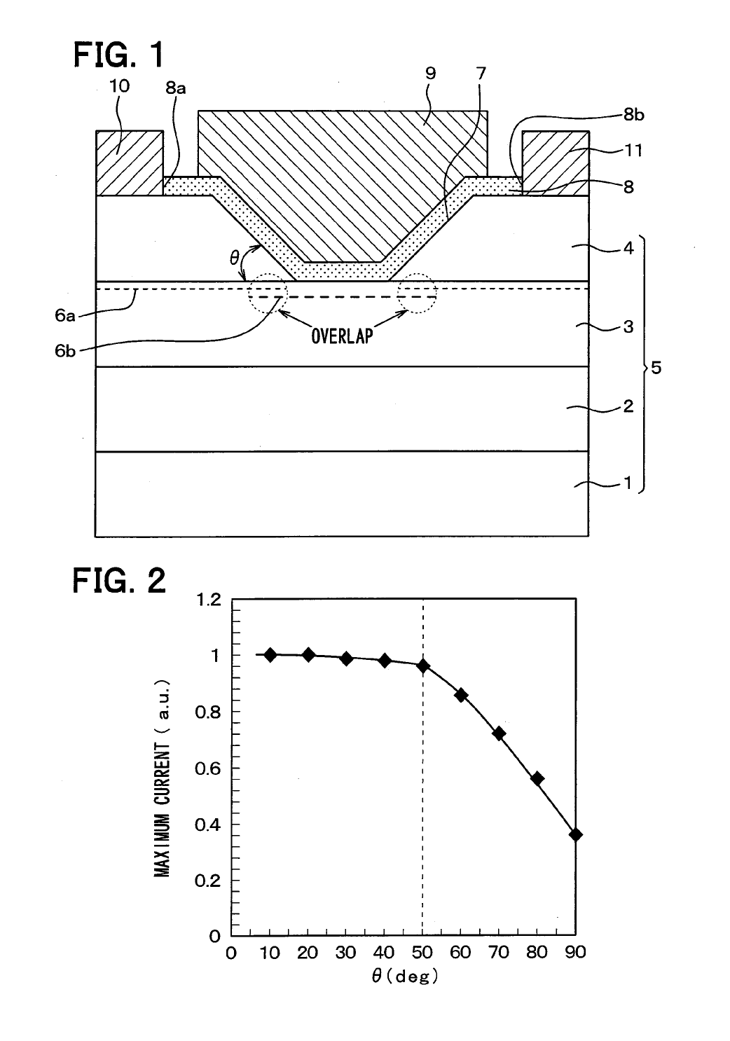

The gate recess 7 of the present embodiment is tapered and gradually becoming narrower in width from an opening side to a bottom surface. More specifically, the gate recess 7 has opposing side surfaces inclined with respect to the interface between the electron transit layer 3 and the electron supply layer 4. In the present embodiment, an angle θ formed by the interface and the respective opposing side surfaces is set to 50° or less. The width of the gate recess 7 means an interval between the opposing side surfaces (a length in the right-left direction on the sheet surface of FIG. 1).

An insulation film 8 is provided on a wall surface of the gate recess 7 and on the electron supply layer 4. A gate electrode 9 made of polysilicon, metal, or the like is embedded in the insulation film 8 provided on the wall surface of the gate recess 7.

The insulation film 8 is provided along the wall surface of the gate recess 7 and the gate electrode 9 is tapered and becoming narrower in width toward the bottom surface of the gate recess 7. It can be said in other words that the gate electrode 9 is inclined with respect to the interface between the electron transit layer 3 and the electron supply layer 4 at portions on the respective side surfaces of the gate recess 7. In addition, a portion of the insulation film 8 provided on the wall surface of the gate recess 7 functions as a gate insulation film.

The insulation film 8 is provided with two openings 8a and 8b at portions on the electron supply layer 4 so as to have the gate recess 7 (gate electrode 9) in between. A source electrode 10 is disposed in one opening 8a and a drain electrode 11 is disposed in the other opening 8b.

The source electrode 10 and the drain electrode 11 are in ohmic contact with the electron supply layer 4 and are electrically connected to the first two-dimensional electron gas layer 6a via the electron supply layer 4. The source electrode 10 and the drain electrode 11 as above are formed, for example, of a Ti/Al layer.

The above has described the configuration of the semiconductor device provided with the HEMT of the present embodiment. An operation of the semiconductor device provided with the HEMT will now be described.

In the semiconductor device provided with the HEMT, the first two-dimensional electron gas layer 6a is formed in the electron transit layer 3 in the vicinity of the interface where the heterojunction is formed with the electron supply layer 4. Because the gate recess 7 is provided so as to reach the electron transit layer 3, the first two-dimensional electron gas layer 6a is not formed at a portion directly below the bottom surface of the gate recess 7. In short, the first two-dimensional electron gas layer 6a is divided by the gate recess 7.

Hence, the semiconductor device provided with the HEMT is capable of obtaining normally-off properties, according to which a channel is not formed between the source electrode 10 and the drain electrode 11 unless a gate voltage at or above a predetermined threshold value is applied to the gate electrode 9 and the semiconductor device remains OFF.

The first two-dimensional electron gas layer 6a is generated by the heterojunction of the electron transit layer 3 and the electron supply layer 4. However, a two-dimensional electron gas layer having electron density high enough to function substantially as a channel is not formed in the electron transit layer 3 at a portion forming the heterojunction with the extremely thin electron supply layer 4. FIG. 1 shows only the first two-dimensional electron gas layer 6a having electron density high enough to function substantially as a channel. That is to say, FIG. 1 does not show the two-dimensional electron gas layer formed in the electron transit layer 3 by the heterojunction with the extremely thin electron supply layer 4.

When a gate voltage at or above the predetermined threshold value is applied to the gate electrode 9, electrons are induced in the electron transit layer 3 at the bottom surface of the gate recess 7 and a region in the vicinity of the bottom surface and the second two-dimensional electron gas layer 6b is generated by the gate voltage. More specifically, because the gate recess 7 is tapered, the second two-dimensional electron gas layer 6b is formed in the electron transit layer 3 at a portion opposing (in contact with) the bottom surface of the gate recess 7 and at portions opposing the respective side surfaces of the gate recess 7 on the bottom surface side via the thin electron supply layer 4 (in the vicinity of the bottom surface of the gate recess 7). In other words, the second two-dimensional electron gas layer 6b is formed at a portion directly below the gate electrode 9 disposed on the bottom surface side of the gate recess 7.

In short, the second two-dimensional electron gas layer 6b is formed so as to partially overlap the first two-dimensional electron gas layer 6a. That is to say, the gate recess 7 is tapered and has the respective side surfaces inclined with respect to the interface between the electron transit layer 3 and the electron supply layer 4 for the second two-dimensional electron gas layer 6b to be formed by partially overlapping the first two-dimensional electron gas layer 6a. Consequently, formation of a region having low electron density in a channel between the source electrode 10 and the drain electrode 11 can be restricted.

When the second two-dimensional electron gas layer 6b is formed, a channel is formed between the source electrode 10 and the drain electrode 11 and electrons flow from the source electrode 10 to the drain electrode 11 by way of the electron supply layer 4, the first two-dimensional electron gas layer 6a, the second two-dimensional electron gas layer 6b, the first two-dimensional electron gas layer 6a, and the electron supply layer 4. The semiconductor device thus switches ON.

A manufacturing method of the semiconductor device provided with the HEMT will now be described briefly.

Firstly, the substrate 5 is prepared by sequentially depositing epitaxially-grown films of the buffer layer 2, the electron transit layer 3, and the electron supply layer 4 on the support substrate 1.

Subsequently, the substrate 5 is dry-etched with a mask to provide the gate recess 7. The gate recess 7 is tapered as described above by applying the dry-etching in such a manner that the side surfaces are etched less as the etching progresses.

Subsequently, the insulation film 8 is formed by CVD (Chemical Vapor Deposition), ALD (Atomic Layer Deposition), or other suitable methods. After the gate electrode 9 is formed by CVD, sputtering, or other suitable methods, the openings 8a and 8b are provided to the insulation film 8 by applying dry-etching with a mask or other suitable methods. Subsequently, the source electrode 10 and the drain electrode 11 are provided. The semiconductor device shown in FIG. 1 is thus manufactured.

As has been described, the gate recess 7 is tapered in the present embodiment for the first and second two-dimensional electron gas layers 6a and 6b to overlap when a gate electrode at or above the predetermined threshold value is applied to the gate electrode 9. Hence, formation of a region having low electron density in a channel between the source electrode 10 and the drain electrode 11 can be restricted. Consequently, a decrease of the maximum current can be restricted.

The angle θ formed by the respective side surfaces of the gate recess 7 and the interface between the electron transit layer 3 and the electron supply layer 4 is set to 50° or less. Hence, a decrease of the maximum current can be restricted as shown in FIG. 2. In FIG. 2, maximum currents are normalized in reference to a maximum current when the formed angle θ is 10°.

That is to say, when the angle θ formed by the respective side surfaces of the gate recess 7 and the interface between the electron transit layer 3 and the electron supply layer 4 becomes greater than 50°, the electron supply layer 4 becomes thicker in the vicinity of the bottom surface of the gate recess 7. Due to the increased thickness, the second two-dimensional electron gas layer 6b is hardly formed in the electron transit layer 3 at portions opposing the respective side surfaces of the gate recess 7 on the bottom surface side. The first and second two-dimensional electron gas layers 6a and 6b therefore no longer overlap and the maximum current decreases abruptly. Hence, by setting the angle θ formed by the respective side surfaces of the gate recess 7 and the interface of the electron transit layer 3 and the electron supply layer 4 to 50° or less, a decrease of the maximum current can be restricted.

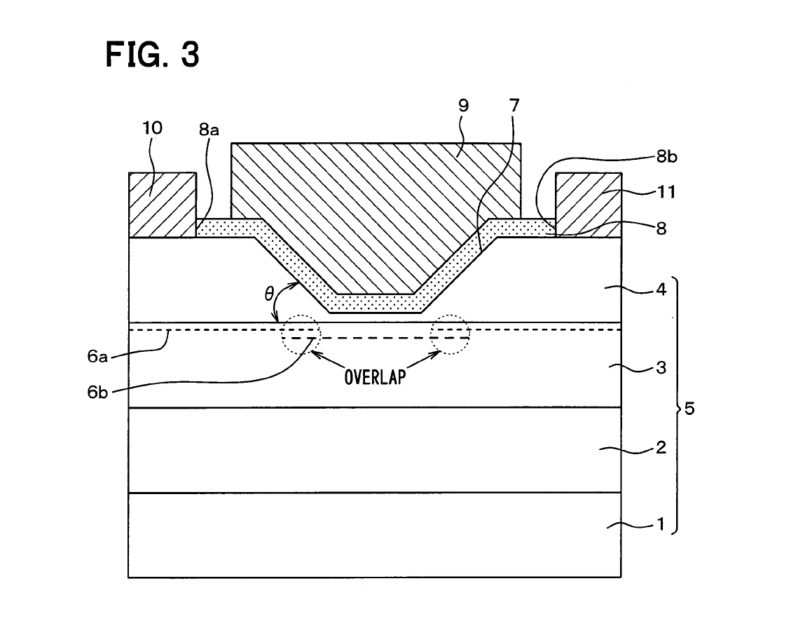

The above has described that the gate recess 7 reaches the electron transit layer 3. However, as shown in FIG. 3, the gate recess 7 may not reach the electron transit layer 3. The gate recess 7 of FIG. 3 obtains the normally-off properties and is therefore required to have a depth deep enough to substantially divide the first two-dimensional electron gas layer 6a. Researches including the inventor conducted a study and discovered that when a thickness of the electron supply layer 4 is 5 nm or less, the first two-dimensional electron gas layer 6a having electron density high enough to function substantially as a channel is not formed in the electron transit layer 3. Hence, the gate recess 7 of FIG. 3 has a depth with which the electron supply layer 4 directly under the bottom surface of the gate recess 7 has a thickness of 5 nm or less.

### Second Embodiment

A second embodiment of the present disclosure will be described. In the present embodiment, a shape of the gate recess 7 of the second embodiment is changed. The rest is the same as the first embodiment above and a description is omitted herein.

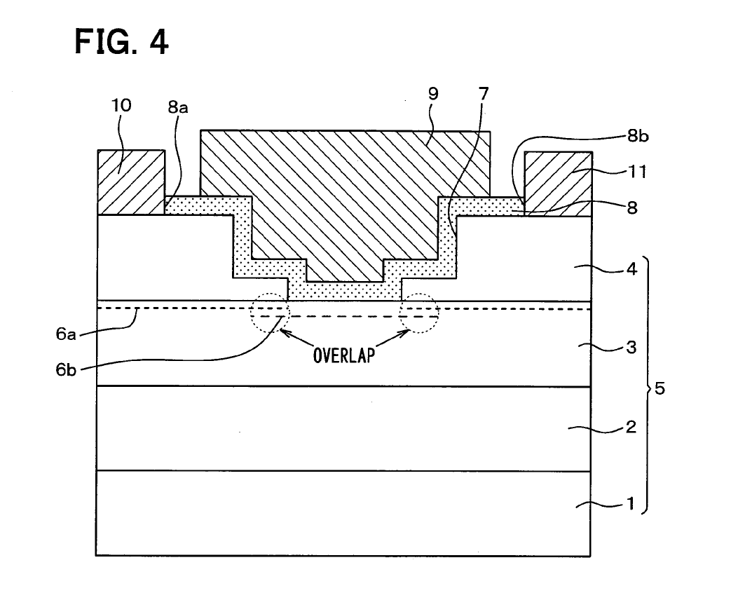

As is shown in FIG. 4, a gate recess 7 of the present embodiment is of a step-like shape in which a width on an opening side is fixed to a width of an opening whereas a width on a bottom surface side is fixed to a width of a bottom surface. In an electron supply layer 4, a portion between the opening side portion of the gate recess 7 and an electron transit layer 3 is sufficiently thick for a first two-dimensional electron gas layer 6a to be formed with electron density high enough to function substantially as a channel. That is to say, in the electron supply layer 4, the portion between the opening side portion of the gate recess 7 and the electron transit layer 3 is made thicker than 5 nm. Hence, in the present embodiment, the first two-dimensional electron gas layer 6a is formed in the electron transit layer 3 up to the bottom surface of the gate recess 7.

In the semiconductor device provided with the HEMT configured as above, when a voltage at or above a predetermined threshold voltage is applied to a gate electrode 9, a second two-dimensional electron gas layer 6b is formed in the electron transit layer 3 at a portion directly below the gate electrode 9, and the first two-dimensional electron gas layer 6a and the second two-dimensional electron gas layer 6b partially overlap. Consequently, advantageous effect same as the advantageous effects of the first embodiment above can be obtained.

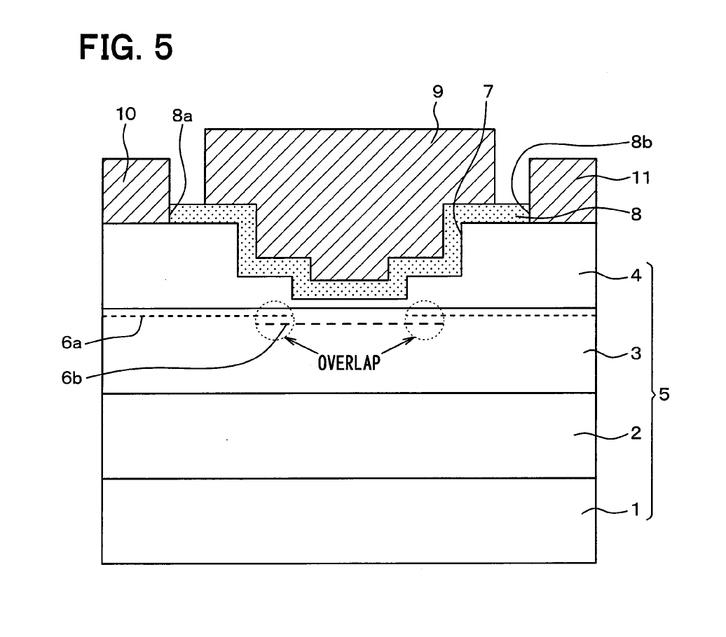

The above has described that the gate recess 7 reaches the electron transit layer 3. However, as shown in FIG. 5, the gate recess 7 may not reach the electron transit layer 3. In the case of the semiconductor device configured as above, the gate recess 7 has a depth with which the electron supply layer 4 directly under the bottom surface of the gate recess 7 has a thickness of 5 nm or less as with the case of FIG. 3.

### Other Embodiments

The respective embodiments have described that the electron transit layer 3 is made of gallium nitride and the electron supply layer 4 is made of aluminum gallium nitride by way of example. However, a combination of the electron transit layer 3 and the electron supply layer 4 can be changed as needed as long as the first and second two-dimensional electron gas layers 6a and 6b are formed as described above, and indium gallium nitride (InGaN), indium aluminum gallium nitride (InAlGaN), indium aluminum nitride (InAlN), and so on may be used as well.

In the respective embodiments above, recesses may be provided to the electron supply layer 4 so as to provide the source electrode 10 and the drain electrode 11 in the recesses. Herein, the recesses may have a depth to reach the electron transit layer 3 for the source electrode 10 and the drain electrode 11 to be disposed on the electron transit layer 3.

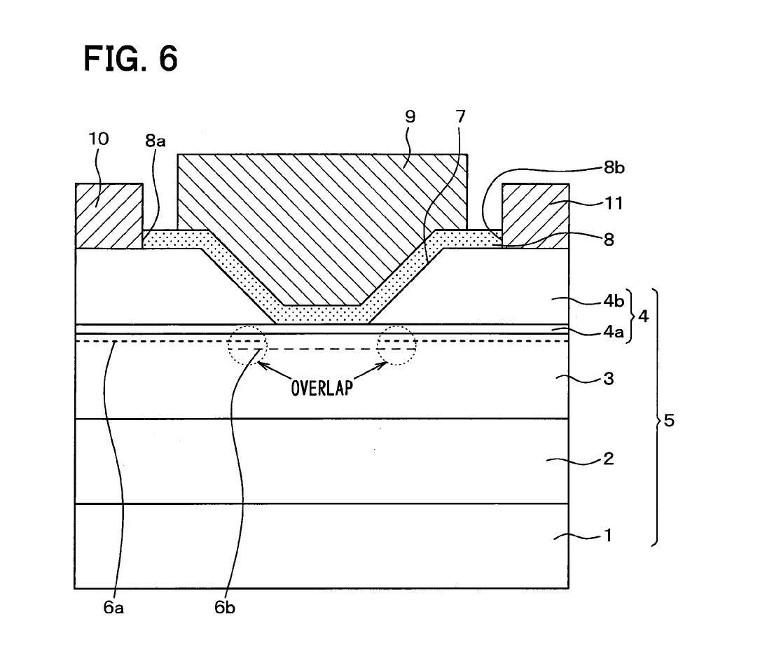

Further, as still another modification of the semiconductor device shown in FIG. 3, the electron supply layer 4 of the first embodiment above may be formed as is shown in FIG. 6 by laminating an aluminum gallium nitride layer 4b on an aluminum nitride (AlN) layer 4a. When configured as above, the aluminum nitride layer 4a serves as an etching stopper and a depth of the gate recess 7 can be controlled at a high degree of accuracy. In addition, the aluminum nitride layer 4a restricts alloy scattering of a carrier. Hence, mobility can be enhanced. Although it is not particularly shown in a drawing, as still another modification of the semiconductor device shown in FIG. 5, the electron supply layer 4 may be formed by laminating the aluminum gallium nitride layer 4b on the aluminum nitride layer 4a.

In the respective embodiments above, a protection film made of SiN, SiO₂, Al₂O₃, and so on may be disposed between the electron supply layer 4 and the insulation film 8 disposed on the electron supply layer 4 (substrate 5). When configured as above, the protection film can restrict a property fluctuation and also lessen a current collapse.

In the respective embodiments above, when aluminum gallium nitride is used as the electron supply layer 4, the electron supply layer 4 may be formed by laminating multiple aluminum gallium nitride layers containing Al and Ga mixed at different crystal ratios.

In the respective embodiments above, the electron transit layer 3 may be formed by sequentially laminating gallium nitride, aluminum gallium nitride, and gallium nitride. When configured as above, lower-end conduction band energy between the electron transit layer 3 and the electron supply layer 4 can be increased. Hence, a threshold voltage Vth can be increased. Further, a leak current between the drain and the source caused by DIBL (Drain Induced Barrier Lowering) can be reduced. When the electron transit layer 3 as above is formed, indium gallium nitride, indium aluminum gallium nitride, indium aluminum nitride, and so on may be used instead of aluminum gallium nitride.

When the semiconductor devices provided with the HEMTs of the respective embodiments above are manufactured, the gate recess 7, the insulation film 8, and the gate electrode 9 may be sequentially provided after the source electrode 10 and the drain electrode 11 are provided to the substrate 5.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

1. A semiconductor device comprising:
a normally-off type HEMT having a first semiconductor layer, a second semiconductor layer providing a heterojunction with the first semiconductor layer and generating a first two-dimensional electron gas layer at the heterojunction, a gate recess arranged in the first semiconductor layer, an insulation film disposed on a wall surface of the gate recess, and a gate electrode disposed on the insulation film, wherein:
the gate recess has a width of a bottom side narrower than an opening side;
the gate electrode is disposed along a side surface of the gate recess; and
when a gate voltage equal to or larger than a predetermined threshold value is applied to the gate electrode, a second two-dimensional electron gas layer generated by the gate voltage is provided in the second semiconductor layer so as to partially overlap the first two-dimensional electron gas layer.

2. The semiconductor device according to claim 1, wherein:
the gate recess has a tapered shape that the width of the gate recess becomes gradually narrower from the opening side to the bottom side; and
side surfaces of the gate recess opposing each other are inclined with respect to a boundary between the first semiconductor layer and the second semiconductor layer.

3. The semiconductor device according to claim 2, wherein:
an angle between the side surface of the gate recess and the boundary between the first semiconductor layer and the second semiconductor layer is equal to or smaller than 50°.

4. The semiconductor device according to claim 1, wherein:
the gate recess has a step-wise shape that a width of a part of the gate recess on the opening side is fixed to a width of an opening of the gate recess, and a width of another part of the gate recess on the bottom side is fixed to a width of a bottom of the gate recess.

5. The semiconductor device according to claim 1, wherein:
the gate recess reaches the second semiconductor layer.

6. The semiconductor device according to claim 1, wherein:
the bottom of the gate recess reaches the second semiconductor layer;
the insulation film covers the bottom and the side surface of the gate recess; and
the gate electrode is disposed along the bottom and the side surface of the gate recess via the insulation film.

7. The semiconductor device according to claim 6, wherein:
the first two-dimensional electron gas layer is disposed in the second semiconductor layer under the first semiconductor layer;
the second two-dimensional electron gas layer is disposed in the second semiconductor layer below the bottom of the gate recess and the second semiconductor layer below a part of the side surface of the gate recess; and
the second two-dimensional electron gas layer and the first two-dimensional electron gas layer overlap in a vicinity of a boundary between the bottom and the side surface of the gate recess.
